(19) United States
(12) Patent Application Publication
(10) Pub. No.: US 2017/0135258 A1
(43) Pub. Date: May 11, 2017

(54) Recovery of Components from Electronic Waste

(71) Applicant: Urban Mining P.B.C., Jacksonville, FL (US)

(72) Inventor: Juan Carlos Villatoro, Jacksonville, FL (US)

(21) Appl. No.: 15/337,043

(22) Filed: Oct. 28, 2016

Related U.S. Application Data
(60) Provisional application No. 62/251,455, filed on Nov. 5, 2015.

(51) Int. Cl. H05K 13/04; B23K 1/018; B23K 3/04; H05K 3/22

(52) U.S. Cl. CPC H05K 13/0486; H05K 3/225; B23K 1/018; B23K 3/04; H05K 2203/176

(57) ABSTRACT

A method of removing components from circuit boards includes the steps of placing in a chamber a plurality of circuit boards having components secured to the board by meltable solder; heating a liquid to a temperature above the melting point of the solder; and melting the solder that secures the components to the board by circulating the heated liquid through the chamber to envelop the boards and the components. Thereafter the liquid, with entrained solder, may be circulated through a heat exchanger and a filter.

### BACKGROUND OF THE INVENTION

This invention relates to the recovery and recycling of electronic waste. Electronic waste includes laptop and desktop computers, phones, televisions, tablets, printers, power supplies, etc. that have been discarded or are broken or obsolete. Such devices contain a great deal of recyclable electronic material, and there are existing processes for recovery or such materials from the waste. Typically the devices are disassembled down to the major parts level, and the major parts components are sorted then sold—for example, plastic cases, power supplies, displays, wiring hamesses, etc.

Many of these devices include printed circuit boards (also known as printed wire boards). A printed circuit board is typically a multi-layered “wafer” of epoxy and metal. The board supports many individual electronic components such as memory chips and CPUs and other chips, transistors, resistors, capacitors, etc. These individual electronic components are typically not removed from the boards; rather, the boards are removed and sold whole. The boards are typically sent to a secondary smelter that grinds up the boards, including all the included components that are still soldered on the boards. The resulting powder is compacted and sent to a primary smelter that melts the powder, separates out some of the valuable elements (such as aluminum and copper and gold) that are present, and discards the rest.

The discarded material includes quantities of other valuable chemicals, such as rare earth metals, but in amounts so small that it is not economically feasible to recover these materials using known recovery processes—so, they are discarded rather than recovered for reuse. To be able to recover more of the individual chemical elements that are present in the components (and in the circuit boards themselves) would reduce the amount of mining and landfills needed, thus addressing a significant environmental problem.

### BRIEF DESCRIPTION OF THE DRAWINGS

FIG. 1 is a schematic illustration of a system that is a first embodiment of the invention;

FIG. 2 is a pictorial illustration of a system that is a second embodiment of the invention;

FIG. 3 is a partial perspective view of a reactor that forms part of the system of FIG. 2;

FIG. 4 is a perspective view of a filter that is included in the reactor of FIG. 3;

FIG. 5 is a schematic flow illustration of the system of FIG. 2;

FIGS. 6 through 9 are schematic illustrations of components that have been removed from circuit boards in use of the systems of FIGS. 1 and 2; and

FIG. 10 is a schematic flow illustration of a system that is a third embodiment of the invention

### DESCRIPTION OF EMBODIMENTS OF THE INVENTION

The process and apparatus of the present invention relate to the recovery of components and chemical elements and epoxy from printed circuit boards (“boards”). “Components” includes electronic items that are soldered onto or are made as one with a board, such as chips, transistors, capacitors, resistors, etc. The invention enables removal of components from their boards in an environmentally friendly manner.

In its broadest sense, the invention involves the immersion of boards in a flowing hot liquid (above the melting point of solder) in order to remove components from a board. Contact between the hot liquid and the board results in melting of the solder that holds the components to the board. The components, no longer secured to the board, are physically separated from the board by the liquid. The components can then be separated from the liquid to recover and recycle them. In addition, the liquid may soften or melt or flake off or otherwise remove one or more layers of material such as epoxy from the board, making it easier to recover recyclable portions of the board such as copper or gold layers. (The term “components” as used herein thus may include a board layer or portion such as the epoxy.)

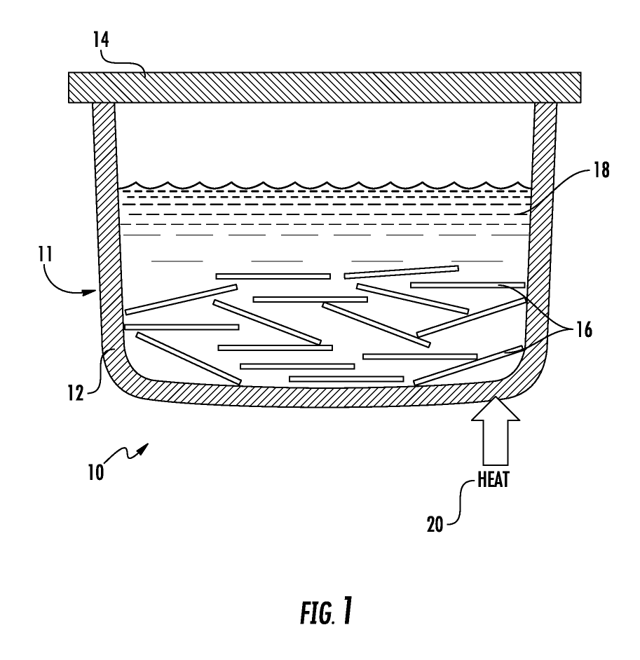

FIG. 1 illustrates schematically a system 10 that is a first embodiment of the invention. The system 10 includes a container 11 that includes a base 12 and a removable lid 14.

The container 11 (somewhat similar to a pressure cooker, for example) is of a construction so that it can safely be heated and as a result pressurized when the lid is sealed to the base. For example, the container 11 can be heated and as a result pressurized to a level of about 100 psi to 300 psi. The container 11 is constructed so that it can withstand relatively high temperatures, for example in the range of 190° F. to 385° F.

One or more circuit boards shown schematically at 16 are placed in the base 12 of the container 11. Each circuit board 16 is typically a wafer made up of multiple layers of epoxy and metal, and may have numerous electronic components soldered on it. The solder is meltable, that is, it is liquefied when raised above its melting point by the application of heat.

A body of liquid 18 is disposed in the container 11. The liquid 18 preferably has the following characteristics: it has a viscosity in the range of the viscosity of water; it is anti-corrosive; and it is odorless. Two suitable liquids are water (preferably distilled water) and ethylene glycol. Water is preferred because it is significantly more environmentally friendly.

The container 11 is then sealed with a lid 14 and then heated via a heat source 20. The heating incidentally increases the pressure in the container 11. The temperature in the container 11 is raised to a temperature above the melting point of the solder on the circuit boards 16, for example, in the range of from about 190° F. to about 385° F. The solder melts, freeing the components from the wafer. In addition, epoxy in the wafer melts.

The boards 16 are maintained in the hot liquid 18 until all or most of the solder is melted. This may be for about 20 minutes. The heat source 20 is then removed, and the container 11 is allowed to cool. As the container 11 cools, the pressure inside the container drops.

When the temperature and pressure of the container 11 are low enough, the container is opened. The boards 16 (wafers) are removed from the liquid 18. Components can be removed from the wafers because the solder that held the components onto the wafers has melted and gone into the liquid. The liquid 18 is filtered. Components and solder and other materials that are present in the liquid 18 are separated. The components can be sorted in a suitable manner, for recycling or resale or other use. The liquid 18 can be cleaned for reuse. This use of the system 10 is environmentally friendly as there are no gases released and no chemicals are used.

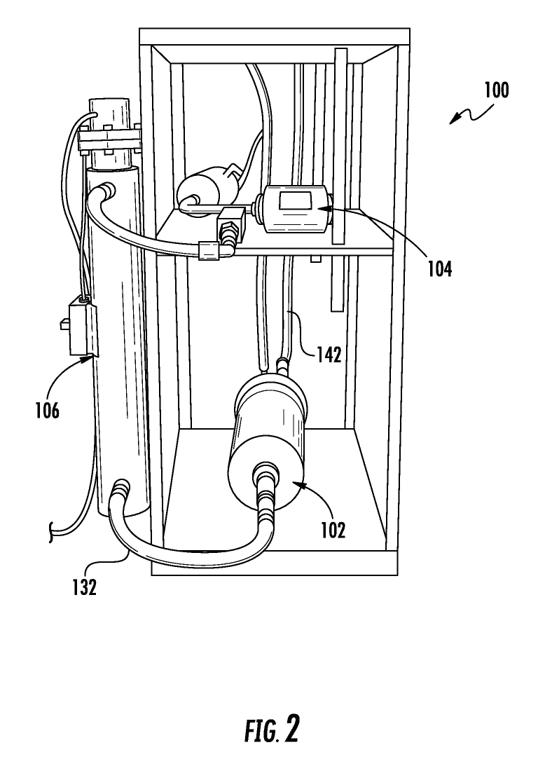

FIGS. 2-5 illustrate an apparatus or system 100 that is a second embodiment of the invention. In comparison to the system 10, which utilizes a single closed container of liquid without any flow of liquid, the system 100 utilizes a stream of heated liquid that circulates in a closed loop through a container having multiple boards therein. The liquid may be selected as described above with reference to the system 10.

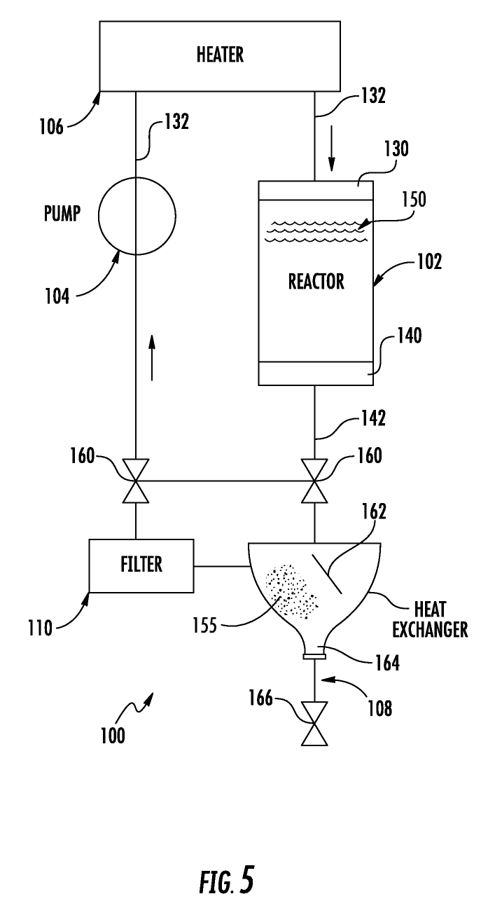

FIG. 5 is a schematic diagram of the system 100. The system 100 includes, as its major component parts, a reactor 102 for receiving boards; a pump 104 for pumping liquid through the reactor 102; a heater 106 for heating the liquid; a heat exchanger 108; and a filter 110. These parts are described below in more detail, following a brief description of the general operation of the system 100, with reference to FIG. 5.

In a first or treating phase of operation of the system 100, the pump 104 pumps liquid through a supply line to the heater 106. The heater 106 heats the liquid, to a temperature high enough to melt the solder on the boards being treated.

The heated liquid flows out of the heater 106 and into the reactor 102. The heated liquid flows through the reactor 102, contacting and treating the boards as described below. As the liquid passes through the reactor 102, the liquid heats the boards and the components thereon, in the process giving up some heat.

The liquid exits the reactor 102 and returns to the pump 104, completing the cycle. That is a first loop of the system. In a second or cool-down phase of operation of the system 100, described below, the liquid passes through a second loop of the system, which includes a heat exchanger 108 and a filter 110.

The reactor 102 is the part of the system 100 that contains the boards being treated, and that receives the flow of hot liquid for treating the boards. The reactor 102 can take many different forms. In the particular embodiment illustrated in FIGS. 2-5, the reactor 102 is generally cylindrical in configuration with a cylindrical outer wall 120 centered on an axis 103.

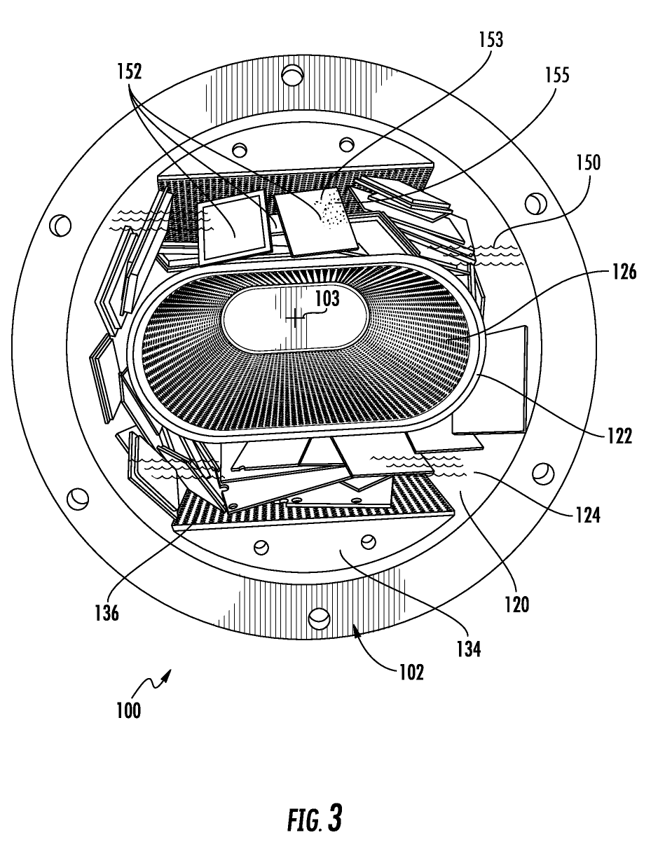

A perforated, oval-shaped inner wall or screen 122 (FIG. 3) is centered in the reactor 102 and extends for most of the length of the reactor. An annular outer chamber 124 is formed between the outer wall 120 and the inner wall 122. An oval-shaped inner chamber 126 is formed inside the inner wall 122. The inner wall 122 is perforated for substantially its entire extent, allowing liquid flow between the outer chamber 124 and the inner chamber 126 of the reactor 102.

An inlet end cap 130 (FIG. 5) is fitted on the inlet end of the reactor 102. Heated water can flow into the reactor 102 through a supply line 132 connected with the inlet end cap 130. The inlet end cap 130 opens into two inlet chambers 134 (FIG. 3) in the reactor 102. The inlet chambers 134 extend for the length of the reactor, along 180 degree opposite sides of the outer wall 120. The inlet chambers 134 have perforated inner walls or screens 136 that open into the outer chamber 124 of the reactor 102. The size of the perforations in the reactor walls (screens) 122 and 136 is selected to enable liquid with entrained solder and epoxy to flow through (and out of the reactor 102), while blocking passage of the components and boards themselves.

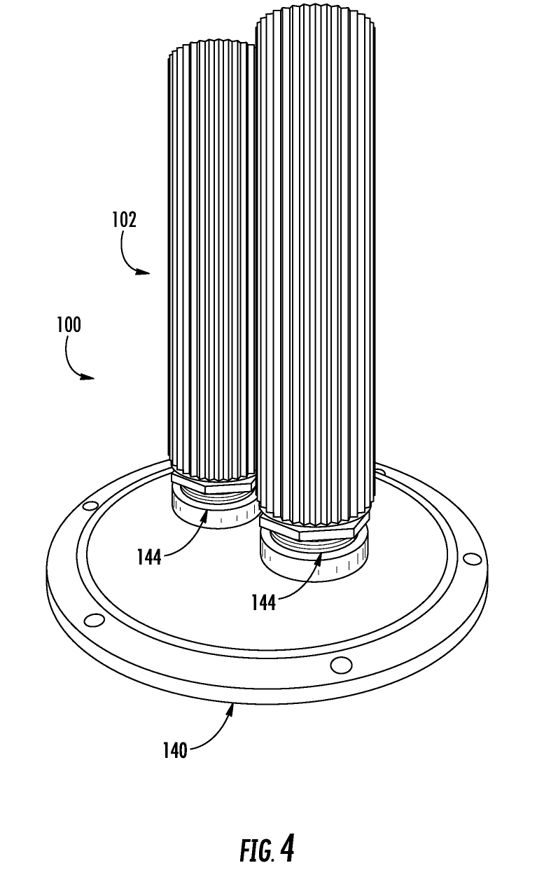

A reactor outlet end cap 140 (FIGS. 4 and 5) is fitted on the outlet end of the reactor 102. The outlet end cap 140 connects with liquid outlet lines 142 for the reactor 102. The outlet end cap 140 also supports two tubular filters 144 that extend into the inner chamber 126 of the reactor 102, inside the inner wall 122. The tubular filters 144 are connected with the liquid outlet lines 142 of the reactor 102.

A first stage of operation of the system 100 commences with heating of a quantity of circulating liquid 150 in the first loop of the system 100. A desired operational temperature is preferably in the range of from about 190° F. to about 385° F. Different solders have different melting points; the temperature of the liquid is selected to be high enough to melt any solder that may be on the boards being treated.

The heated liquid 150 is circulated through the reactor 102 for a time period that is long enough to melt solder and thus allow separation of substantially all components from circuit boards. This time period may vary; in working embodiments it has ranged from 20 minutes to 40 minutes, for example.

More specifically, a quantity of boards 152 having components 153, solder 155, and epoxy 157 are placed in the outer chamber 124 of the reactor 102 and the reactor is sealed. Heated liquid 150 is pumped into the reactor 102 through the inlet end cap 130. The heated liquid 150 flows into the inlet chambers 134, and radially inward through their perforated inner walls 136 into the outer chamber 124. The liquid 150 flows over the boards 152 and treats the boards.

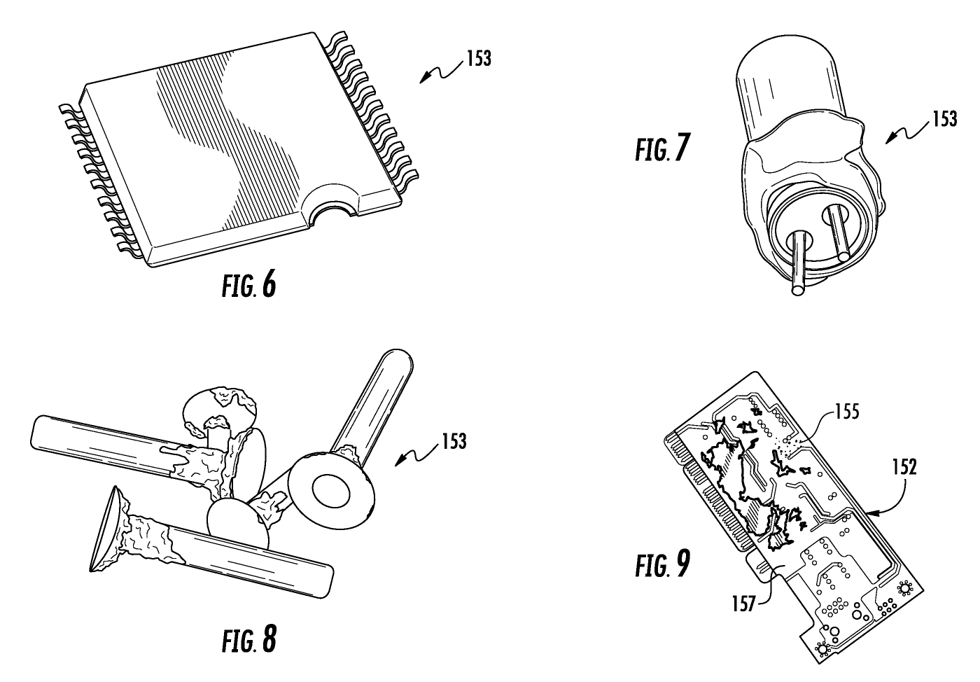

The solder 155 is melted by the hot liquid 150, and the components 153 separate from the board 152 itself. This process works on both surface mount components and pin mount components. The components 153 are removed intact, including the pins, examples being shown in FIGS. 6, 7 and 8. In some embodiments, up to 100% of components 153 are removed from the boards 152. The solder 155 is removed from the boards 152, and is entrained in the flowing liquid 150. In addition, some or all of the epoxy 157 on the boards 152 melts or flakes off, especially the outermost layer, as the melting point of the epoxy is typically lower than the melting point of solder. This is shown schematically in FIG. 9, which illustrates a board 152 with epoxy 157 flaking off. In some embodiments, up to 99% of the epoxy is removed from the boards 152.

The liquid 150 thence flows from the outer chamber 124, through the perforated inner wall 122, into the oval-shaped inner chamber 126 of the reactor 102. The flowing liquid 150 transports any entrained solder 155 and epoxy 152. The liquid 150 then flows inward through the walls of the tubular filters 144 to the insides of the filters 144. The filtered liquid 150 then flows out of the reactor 102 through the outlet end cap 140, specifically, the outlet lines 142. The pump 104 recirculates the liquid 150.

During the time period in which the boards 152 are contacted by the hot liquid 150, solder 155 on the boards melts, and is entrained in the liquid. Also, the epoxy layers 157 in the boards 152 melt, and the epoxy also becomes entrained in the liquid 150, or is at least partially separated from the other materials (layers) of the boards. The flow of hot liquid 150 is maintained for a long enough time period for these things to happen. During this time, the screens 122 and 136 in the reactor 102 keep the removed components 153 in the reactor, while allowing the fluid 150 and solder 155 and epoxy 157 to flow out.

In a second stage of operation, once the treatment of the boards 152 is concluded, the temperature of the system 100 is reduced so that the treated boards 152 and components 153 can be removed for recovery. Specifically, in this second stage, the heater 106 is turned off, and two valves 160 are reset so that the liquid exiting the reactor 102 flows also through a second loop including the heat exchanger 108 and the filter 110 before returning to the pump 104.

The heat exchanger 108 is cooled with a separate flow of cold or ambient temperature liquid. This cooling helps to solidify the melted solder 155 in the liquid 150, and the solder 155 and epoxy 157 can settle out of the liquid and be accumulated in the heat exchanger 108 for removal. The heat exchanger 108 may include a baffle or other structure 162 that captures solids from the liquid 150 flowing through the heat exchanger.

The fluid output of the heat exchanger 108 is directed to the filter 110, which removes finer particulate matter from the liquid 150. The filtered liquid 150 is sent again through the reactor 102 and the heat exchanger 108, removing more solids from the reactor, and enabling further filtering of the solids and cooling of the system components.

When the temperature in the system 100 drops low enough, for example to between room temperature and about 150° F., cooling and filtering in the second stage of operation are substantially completed, and the pump 104 is turned off. The cooling portion of the cycle may last for about ten minutes or more, depending on the size and structure and configuration of the system 100.

A strainer and valve 164 on the heat exchanger 108 allow liquid 150 to be withdrawn from the heat exchanger, after the cycle is completed and the pump 104 is turned off. The heat exchanger 108 can be opened and any material therein removed. The filter 110 also can be cleaned. Finally, the reactor 102 itself can be opened to remove treated boards 152 and components 153. Quick disconnects may be provided on the various parts of the system 100, to enable the parts to be taken offline and cleaned without loss of liquid.

In one embodiment, the temperature is only dropped to 150° F., rather than to room temperature. This enables quicker reheating to operating temperature, and minimizes the possibility of thermal shock to parts of the system 100 including the pump 104 when the system is restarted and reheated.

The removal of the components 153 from the boards 152 is not done chemically, via any chemical reaction. Rather, it is the melting of the solder, from the heat of the flowing liquid 150, that enables the removal of the components 153 from the boards 152. Similarly, it is the heat of the flowing liquid 150 that causes the epoxy layers (at least the outer epoxy layer) of the board 152 to dissolve or flake off. This leaves the metal portions of the board intact, such as copper and gold, thus enabling recycling of those materials. The flowing liquid 150 additionally serves to transport the melted solder and epoxy portions to a point at which they can be removed from the liquid stream.

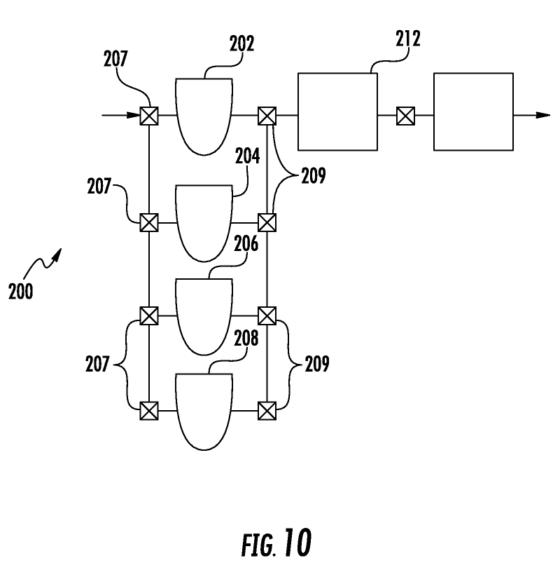

FIG. 10 illustrates a third embodiment of the invention. In the third embodiment of the invention, plural recovery containers are provided and are interconnected for continuous operation.

Specifically, the system 200 includes a plurality of (in this case four) reactors 202, 204, 206, and 208. The reactor 202-208 are connected in parallel with each other by a plurality of sets of inlet and outlet valves 209, associated one set with each of the reactors.

Downstream of the reactors 202-208 is a single unit 210 that operates as a heat exchanger and solidifier and collector and strainer, similar to the heat exchanger 108 that forms part of the second embodiment. Downstream of the heat exchanger 210 is a filter 212, similar to the filter 110 that forms part of the second embodiment. Upstream of the reactors 202-208 are the pump and heater (not shown).

In operation of the system 200, one or more of the reactors 208 can be online at all times. At some point, each one of the reactors 202-208 will need to go offline for cooling and cleaning. At that point, the associated valves are reset for that purpose, while the other reactors continue to operate.

1. A method of removing components from circuit boards, comprising the steps of:
placing in a chamber a plurality of circuit boards having components secured to the boards by meltable solder;
heating a liquid to a temperature above the melting point of the solder; and
melting the solder that secures the components to the board by circulating the heated liquid through the chamber to envelop the boards and the components.

2. A method as set forth in claim 1, wherein the step of melting the solder by circulating the heated liquid includes the step of entraining melted solder in the heated liquid, and the method further includes the step of thereafter removing the entrained solder from the liquid.

3. A method as set forth in claim 2 wherein the step of heating a liquid includes heating the liquid to a temperature in the range of from about 290 degrees Fahrenheit to about 385 degrees Fahrenheit.

4. A method as set forth in claim 1 wherein the step of heating a liquid includes heating water to a temperature in the range of from about 190 degrees Fahrenheit to about 385 degrees Fahrenheit.

5. A method as set forth in claim 1 wherein the step of circulating the heated liquid includes the step of removing epoxy from the circuit boards to de-layer at least partially the circuit boards.

6. A method as set forth in claim 1 further including the steps of;
stopping heating of the liquid;
thereafter continuing to circulate the liquid through the chamber by a pump; and
redirecting the fluid exiting the chamber into a heat exchanger to cool the liquid and cause solder to settle out of the liquid.

7. A method as set forth in claim 1 wherein the step of circulating the heated liquid includes the steps of passing the heated liquid into the chamber through an inlet of the chamber, flowing the liquid through the chamber, and removing the heated liquid from the chamber through an outlet of the chamber.

8. A method of treating circuit boards that are located in a chamber and that have components secured to the circuit boards with meltable solder, the method including the steps of:
melting the solder that holds the components on the boards by circulating a heated liquid through the chamber over the boards and the components;
entraining melted solder in the liquid;
passing liquid that exits the chamber to a heat exchanger to cool the liquid and solidify at least some of the solder; and
passing liquid that exits the heat exchanger through a filter.

9. A method as set forth in claim 8 wherein the step of circulating a heated liquid comprises circulating heated water.

10. A system for treating circuit boards having components soldered thereon, comprising:
a container having a liquid inlet and a liquid outlet and a chamber between the liquid inlet and the liquid outlet;
a pump connected with the liquid inlet of the container configured to pump liquid into the liquid inlet and thence into the chamber and out of the liquid outlet;
a heater for heating the liquid that is being pumped into the liquid inlet to a temperature above the melting point of solder;
a heat exchanger for cooling the liquid that flows out of the chamber through the liquid outlet, to a temperature below the melting point of solder; and
a filter for filtering liquid that has flowed through the heat exchanger.

11. A system as set forth in claim 10 wherein the container includes at least one screen in the chamber for blocking flow of components out of the chamber while allowing flow of liquid out of the chamber.

12. A system as set forth in claim 11 wherein the liquid is water that is at a temperature in the range of from about 290 degrees Fahrenheit to about 385 degrees Fahrenheit.
